(19) United States
(12) Patent Application Publication
(10) Pub. No.: US 2017/0212166 A1
(43) Pub. Date: Jul. 27, 2017

(54) PROBE HEAD ASSEMBLIES WITH CONSTRAINED INTERNAL MOTION AND PROBE SYSTEMS INCLUDING THE PROBE HEAD ASSEMBLIES

(71) Applicant: Cascade Microtech, Inc., Beaverton, OR (US)

(72) Inventor: Brandon Liew, Beaverton, OR (US)

(21) Appl. No.: 15/007,459

(22) Filed: Jan. 27, 2016

(51) Int. Cl. G01R 31/28; G01R 1/073

(52) U.S. Cl. CPC G01R 31/2887; G01R 1/07364

(57) ABSTRACT

Probe head assemblies with constrained internal motion and probe systems including the probe head assemblies are disclosed herein. The probe head assemblies include a contacting structure, an orientation-regulating structure, and a support frame. The contacting structure includes a plurality of conductive probes configured to physically and electrically contact corresponding contact pads on the DUT. The support frame is configured to support the contacting structure and the orientation-regulating structure. The orientation-regulating structure supports the contacting structure and is configured to permit translational motion of the contacting structure relative to the support frame along a contacting axis. The orientation-regulating structure further is configured to resist translational motion of the contacting structure relative to the support frame in any direction that is at least substantially perpendicular to the contacting axis. The orientation-regulating structure may include a compound linear flexure.

### Field Of The Disclosure

The present disclosure is directed to probe head assemblies with constrained internal motion and to probe systems that include the probe head assemblies.

### BACKGROUND OF THE DISCLOSURE

Probe head assemblies often are utilized to physically and/or electrically contact a device under test (DUT), such as to permit testing of the DUT. These probe head assemblies generally include a plurality of conductive probes, and the probes may establish the contact with the DUT. Often, the probes will be configured to deflect upon contact with the DUT, thereby permitting at least a threshold amount of overdrive. The overdrive may be utilized to ensure that all of the probes contact the DUT, to ensure at least a threshold contact force between each probe and the DUT, and/or to ensure less than a threshold contact resistance between each probe and the DUT. However, a magnitude of this overdrive may be relatively small due to limitations on a magnitude of deflection that may be experienced by a given probe without damage to the given probe. This may make it difficult to precisely control the contact force between each probe and the DUT.

In certain circumstances, it may be desirable to simultaneously contact and/or test a plurality of DUTs that may be present on a substrate. Under these conditions, the probe head assembly may include a plurality of contacting regions, with each of these contacting regions being configured to contact a respective DUT. In some instances, a number of contacting regions in a given probe head assembly may be less than a number of DUTs to be tested on a given substrate. In these instances, probe systems that include the probe head assemblies may be designed such that the probe head assembly is stepped and/or otherwise moved across a surface of the substrate, thereby permitting testing of a greater number of DUTs than may be tested at a given time.

In such a configuration, the probe head assembly may, at times, be oriented relative to the substrate such that fewer than all of the contacting regions are contacting respective DUTs (e.g., such that one or more of the contacting regions extends past an edge of the substrate while a remainder of the contacting regions is contacting respective DUTs). Such an orientation may be referred to herein as off-stepping and/or as an off-stepped orientation.

When the probe head assembly is in the off-stepped orientation, a torque may be applied to the probe head assembly by the substrate. This torque may tend to tip, tilt, and/or rotate the probe head assembly relative to the substrate, thereby making it difficult to maintain contact, to maintain sufficient contact, and/or to maintain a desired level of contact between all contacting regions that are oriented to contact a corresponding DUT and the corresponding DUT.

The probe head assemblies with constrained internal motion and/or probe systems that include probe head assemblies with constrained internal motion, which are disclosed herein, may be utilized to provide additional overdrive that is not reliant upon deflection of the probes and/or to permit more precise control of the contact force between each probe and the DUT. In addition, these probe head assemblies and/or probe systems may provide this additional overdrive and/or more precise control while resisting rotation of the probe head assembly relative to the substrate.

### SUMMARY OF THE DISCLOSURE

Probe head assemblies with constrained internal motion and probe systems including the probe head assemblies are disclosed herein. The probe head assemblies include a contacting structure, an orientation-regulating structure, and a support frame. The contacting structure includes a plurality of conductive probes configured to physically and electrically contact corresponding contact pads on the DUT. The support frame is configured to support the contacting structure and the orientation-regulating structure.

The orientation-regulating structure supports the contacting structure and extends at least partially between the contacting structure and the support frame. The orientation-regulating structure is configured to permit translational motion of the contacting structure relative to the support frame along a contacting axis. The orientation-regulating structure further is configured to resist translational motion of the contacting structure relative to the support frame in any direction that is at least substantially perpendicular to the contacting axis. The orientation-regulating structure further may be configured to resist rotational motion of the contacting structure relative to the support frame about any axis. The orientation-regulating structure may include a compound linear flexure.

### BRIEF DESCRIPTION OF THE DRAWINGS

FIG. 1 is a schematic representation of examples of a probe head assembly, according to the present disclosure, which may form a portion of a probe system.

FIG. 2 is a schematic side view illustrating examples of a portion of a probe head assembly, according to the present disclosure, including an orientation-regulating structure in an undeflected relative orientation.

FIG. 3 is a schematic side view of the probe head assembly of FIG. 2 in a deflected relative orientation.

FIG. 4 is a schematic side view of an example of an orientation-regulating structure according to the present disclosure, in the form of a compound linear flexure, illustrated in an undeflected relative orientation.

FIG. 5 is a schematic side view of the compound linear flexure of FIG. 4 in a deflected relative orientation.

FIG. 6 is a schematic bottom view of the orientation-regulating structure of FIGS. 4-5.

FIG. 7 is a schematic side view of an example of an orientation-regulating structure according to the present disclosure, in the form of a compound linear flexure, in an undeflected relative orientation.

FIG. 8 is a schematic bottom view of the orientation-regulating structure of FIG. 6.

FIG. 9 is a less schematic side view of an example of a probe head assembly according to the present disclosure.

### DETAILED DESCRIPTION AND BEST MODE OF THE DISCLOSURE

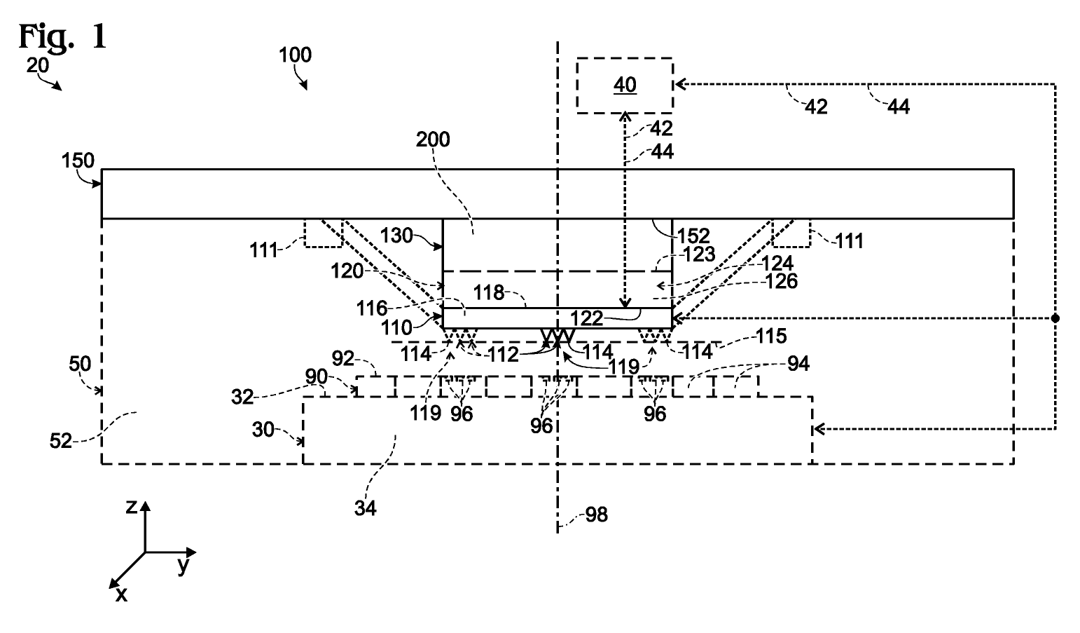

FIGS. 1-9 provide examples of probe head assemblies 100, according to the present disclosure, and/or of probe systems 20 that include probe head assemblies 100. Elements that serve a similar, or at least substantially similar, purpose are labeled with like numbers in each of FIGS. 1-9, and these elements may not be discussed in detail herein with reference to each of FIGS. 1-9. Similarly, all elements may not be labeled in each of FIGS. 1-9, but reference numerals associated therewith may be utilized herein for consistency. Elements, components, and/or features that are discussed herein with reference to one or more of FIGS. 1-9 may be included in and/or utilized with any of FIGS. 1-9 without departing from the scope of the present disclosure. In general, elements that are likely to be included in a particular embodiment are illustrated in solid lines, while elements that are optional are illustrated in dashed lines. However, elements that are shown in solid lines may not be essential and, in some embodiments, may be omitted without departing from the scope of the present disclosure.

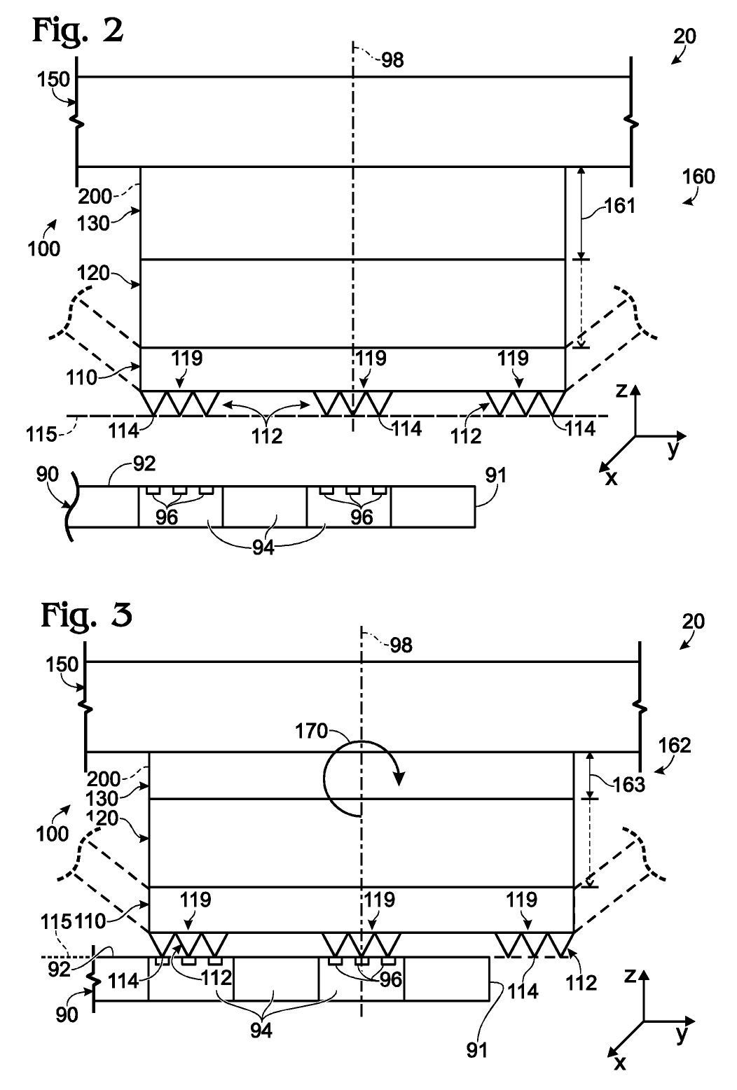

FIG. 1 is a schematic representation of examples of a probe head assembly 100, according to the present disclosure, that may form a portion of a probe system 20. FIGS. 2-3 are schematic side views illustrating examples of a portion of probe head assembly 100 in an undeflected relative orientation 160, as illustrated in FIG. 2, and in a deflected relative orientation 162, as illustrated in FIG. 3.

Probe head assembly 100 may be configured to contact, such as to electrically and/or physically contact, a device under test (DUT) 94 along a contacting axis 98. As illustrated in solid lines in FIGS. 1-3, probe head assembly 100 includes a contacting structure 110, which includes a plurality of conductive probes 112 that is configured to physically and electrically contact corresponding contact pads 96 on one or more DUTs 94. Probe head assembly 100 also includes an orientation-regulating structure 130 and a support frame 150, which is configured to support the contacting structure and the orientation-regulating structure.

Orientation-regulating structure 130 supports contacting structure 110 and extends at least partially between the contacting structure and support frame 150. As illustrated in dashed lines in FIG. 1 and in solid lines in FIGS. 2-3, probe head assembly 100 also may include a backing plate 120. Backing plate 120 may include and/or be a rigid, or at least substantially rigid, backing plate 120, may support contacting structure 110, and/or may be supported by support frame 150. In addition, backing plate 120 may extend at least partially between contacting structure 110 and orientation-regulating structure 130. Thus, orientation-regulating structure 130 may support contacting structure 110 via backing plate 120 and/or may extend at least partially between the backing plate and the support frame.

Orientation-regulating structure 130 may be configured to permit translational motion of contacting structure 110 and/or of backing plate 120 relative to support frame 150 along contacting axis 98 and also to resist translational motion of the contacting structure and/or of the backing plate relative to the support frame in any direction that is, or in all directions that are, perpendicular, or at least substantially perpendicular, to the contacting axis. In addition, orientation-regulating structure 130 may be configured to resist rotational motion of contacting structure 110 and/or of backing plate 120 relative to support frame 150 about any axis, or all axes.

Stated another way, and as discussed in more detail herein, orientation-regulating structure 130 may exhibit a greater resistance to translational motion of the contacting structure and/or of the backing plate relative to the support frame in directions, or in all directions, that are perpendicular to the contacting axis when compared to along the contacting axis, or in directions that are parallel, or at least substantially parallel, to the contacting axis. Similarly, orientation-regulating structure 130 may exhibit a greater resistance to rotational motion of the contacting structure and/or of the backing plate relative to the support frame about any axis, or all axes, when compared to translational motion along the contacting axis.

Stated yet another way, a deformation force of a given magnitude that is applied to the orientation-regulating structure, such as via contact between the contacting structure and the DUT, may cause the contacting structure and/or the backing plate to be displaced, or to move, relative to the support frame. However, the magnitude of this displacement may vary depending upon the location and/or direction of the deformation force, with deformation forces that are directed along the contacting axis causing the greatest amount of displacement and deformation forces that are not directed along the contacting axis causing a significantly lesser amount of displacement. This is discussed in more detail herein.

As illustrated in dashed lines in FIG. 1, probe system 20 further may include a chuck 30 that includes a support surface 32. Support surface 32 may be configured to operatively support a substrate 90 that includes one or more DUTs 94. Probe system 20 also may include an enclosure 50 that defines an enclosed volume 52. At least a portion of chuck 30, support surface 32, and/or probe head assembly 100 may be included and/or oriented within enclosed volume 52, as illustrated.

Probe system 20 further may include a signal generation and analysis assembly 40. Signal generation and analysis assembly 40 may be configured to provide a test signal 42 to DUT 94 via probe head assembly 100 and/or via chuck 30. Additionally or alternatively, signal generation and analysis assembly 40 may be configured to receive a resultant signal 44 from DUT 94 via probe head assembly 100 and/or via chuck 30.

As further illustrated in dashed lines in FIG. 1 and in solid lines in FIGS. 2-3, substrate 90 may include a plurality of DUTs 94, which may be oriented and/or spaced-apart in an array on a surface 92 of the substrate. In addition, contacting structure 110 may include a plurality of spaced-apart contacting regions 119 that may be oriented, located, and/or positioned to contact a corresponding subset of the plurality of DUTs 94.

During operation of probe systems 20 that include probe head assemblies 100 according to the present disclosure, probe head assembly 100 may be aligned with one or more DUTs 94 on substrate 90. This may include aligning the probe head assembly with the one or more DUTs within a plane that is parallel, or at least substantially parallel, to surface 92 of substrate 90 and/or within a plane that is perpendicular, or at least substantially perpendicular, to contacting axis 98. As examples, this may include aligning the probe head assembly with the one or more DUTs in the X and Y-directions of FIGS. 1-3.

The alignment may be accomplished in any suitable manner, such as by translating and/or rotating chuck 30 relative to probe head assembly 100 via a chuck stage 34, as illustrated in FIG. 1. Additionally or alternatively, the alignment may be accomplished by translating and/or rotating probe head assembly 100 relative to chuck 30.

Subsequently, conductive probes 112 of probe head assembly 100 may be brought into contact with corresponding contact pads 96 of corresponding DUTs 94, such as to provide physical and/or electrical contact between the conductive probes and the contact pads. This contact, which is illustrated in FIG. 3, may be established in any suitable manner and generally will include translation of chuck 30 toward probe head assembly 100 along contacting axis 98 and/or in the positive Z-direction. Such translation of chuck 30 may be accomplished via and/or utilizing chuck stage 34 of FIG. 1. Additionally or alternatively, the contact may be established via translation of probe head assembly 100, or at least contacting structure 110 thereof, toward chuck 30 and/or substrate 90. This may include translation of the probe head assembly toward chuck 30, along contacting axis 98, and/or in the negative Z-direction.

Prior to contact between probe head assembly 100, or contacting structure 110 thereof, and substrate 90, or DUT(s) 94 thereof, probe head assembly 100 and/or orientation-regulating structure 130 thereof may be in undeflected relative orientation 160 and/or may define and/or establish an undeflected distance 161 between support frame 150 and backing plate 120 and/or between support frame 150 and contacting structure 110. This is illustrated in FIG. 2.

Responsive to contact between probe head assembly 100, or contacting structure 110 thereof, and substrate 90, or DUT(s) 94 thereof, orientation-regulating structure 130 may permit translation of contacting structure 110 along contacting axis 98 and/or to deflected relative orientation 162, as illustrated in FIG. 3. This translation of contacting structure 110 may be in the positive Z-direction and/or may be toward support frame 150. Thus, a deflected distance 163, as also illustrated in FIG. 3, between support frame 150 and backing plate 120 and/or between support frame 150 and contacting structure 110 may be less than undeflected distance 161 that is illustrated in FIG. 2. Stated another way, the translation of contacting structure 110 may permit additional overdrive of probe head assembly 100 toward substrate 90 when compared to probe systems that do not include orientation-regulating structure 130 according to the present disclosure. In addition, and as also discussed, orientation-regulating structure 130 further is configured to limit, restrict, and/or resist translational motion of contacting structure 110 relative to support frame 150 in any direction that is, or in all directions that are, perpendicular to contacting axis 98, such as the X and/or Y-directions of FIGS. 1-3.

Orientation-regulating structure 130 also is configured to limit, restrict, and/or resist rotational motion of contacting structure 110 relative to support frame 150 about any axis, or all axes, such as about the X, Y, and/or Z-axes of FIGS. 1-3. This is illustrated in FIGS. 2-3, where, as discussed, one or more contacting regions 119 of probe head assembly 110 are oriented relative to the probe head assembly such that the one or more contacting regions extend past an edge 91 of the substrate. Stated another way, and as discussed in more detail herein, orientation-regulating structure 130 may be configured to permit the contacting assembly and/or the backing plate to rotate by less than a threshold angle relative to the support frame.

Thus, and as illustrated in FIG. 3, the one or more contacting regions that extend past edge 91 do not contact substrate 90 while a remainder of the contacting regions is contacting respective DUTs on substrate 90. Such a configuration may generate a torque 170 that acts upon probe head assembly 100. This torque may tend to urge contacting structure 110 to rotate relative to substrate 90. Such rotation, if permitted, may be detrimental to the performance of probe system 20 and/or probe head assembly 100, as the rotation may preclude one or more contacting regions 119 from forming a desired level of, or potentially even any, physical and/or electrical contact with substrate 90. However, orientation-regulating structure 130 limits, restricts, and/or resists this rotation, thereby maintaining alignment between probe head assembly 100 and substrate 90 and/or maintaining a contacting plane 115 of probe tips 114 of conductive probes 112 parallel, or at least substantially parallel, to surface 92 of substrate 90 despite the application of torque 170 to the probe head assembly.

Orientation-regulating structure 130 may include any suitable structure that may be adapted, configured, designed, constructed, and/or fabricated to permit translational motion of the contacting structure relative to the support frame along the contacting axis. The orientation-regulating structure also may include any suitable structure that may be adapted, configured, designed, constructed, and/or fabricated to resist translational motion of the contacting structure relative to the support frame in directions that are perpendicular to the contacting axis. Stated another way, the orientation-regulating structure may permit relative motion between contacting structure 110 and/or backing plate 120 and support frame 150 along a permitted degree of freedom and may resist relative motion of the contacting structure and/or of the backing plate relative to the support frame along all other degrees of freedom.

In addition, the orientation-regulating structure may include any suitable structure that may resist rotation, or all rotation, of the contacting structure relative to the support frame. Stated another way, the orientation-regulating structure may be adapted, configured, designed, constructed, and/or fabricated to resist tilting of the contacting structure relative to the support frame when the probe head assembly operatively contacts the DUT.

As an example, and as illustrated in FIG. 1, backing plate 120, when present, may include and/or define a contacting structure-supporting surface 122 and a contacting structure-opposed surface 123. The contacting structure-supporting surface may face toward, may be operatively attached to, and/or may support contacting structure 110, while the contacting structure-opposed surface may face away from contacting structure 110 and/or may be operatively attached to orientation-regulating structure 130. In addition, support frame 150 may include an orientation-regulating structure supporting surface 152 that may face toward, may be operatively attached to, and/or may support orientation-regulating structure 130. Under these conditions, orientation-regulating structure 130 may be configured to maintain contacting structure-supporting surface 122 parallel, or at least substantially parallel, to orientation-regulating structure-supporting surface 152 during translational motion of contacting structure 110 and/or backing plate 120 relative to support frame 150 and/or along contacting axis 98. Alternatively, orientation-regulating structure 130 may be configured to maintain a fixed, or at least substantially fixed, angle of intersection between a plane that is defined by the contacting structure-supporting surface and a plane that is defined by the orientation-regulating structure-supporting surface during translational motion of the contacting structure and/or of the backing plate relative to the support frame and/or along the contacting axis.

As discussed, contact between contacting structure 110 and substrate 90 may cause probe head assembly 100 and/or orientation-regulating structure 130 thereof to deflect from undeflected relative orientation 160 of FIG. 2 to deflected relative orientation 162 of FIG. 3. In addition, it is within the scope of the present disclosure that, upon deflection from the undeflected relative orientation to the deflected relative orientation, the orientation-regulating structure may exhibit a restoring force on contacting structure 110 and/or on backing plate 120 that urges the probe head assembly toward the undeflected orientation. The restoring force may be proportional, at least substantially proportional, linearly proportional, or at least substantially linearly proportional, to a distance that the contacting structure and/or the backing plate is deflected from the undeflected relative orientation. As an example, the restoring force may be proportional to a difference between undeflected distance 161 of FIG. 2 and deflected distance 163 of FIG. 3.

In general, the regulated and/or controlled motion between contacting structure 110 and/or backing plate 120 and support frame 150 cannot be provided by traditional coil springs and/or pivoting mounts that may be utilized in traditional probe head assemblies that do not include orientation-regulating structures 130 according to the present disclosure. As such, probe head assemblies 100 and/or orientation-regulating structures 130 thereof may not include, or be, a coil spring, an array of coil springs, and/or a gimbal mount.

Orientation-regulating structure 130 may not be perfectly rigid in directions that are perpendicular to the contacting axis. As such, it is within the scope of the present disclosure that orientation-regulating structure 130 may exhibit a stiffness along the contacting axis that may be different from, or less than, a stiffness of the orientation-regulating structure along one or more other axes that are perpendicular to the contacting axis. Stated another way, a resistance to deformation of the orientation-regulating structure, as measured along the contacting axis, may be different from, or less than, a resistance to deformation of the orientation-regulating structure as measured in directions that are perpendicular to the contacting axis. Stated yet another way, a resistance to relative motion between the contacting structure and/or the backing plate and the support frame, as provided by the orientation-regulating structure, may be different, or less, when measured along the contacting axis when compared to directions that are perpendicular to the contacting axis.

As an example, the orientation-regulating structure may exhibit a stiffness along the contacting axis of at least 0.01 Newtons/micrometer, at least 0.05 Newtons/micrometer, at least 0.1 Newtons/micrometer, at least 0.2 Newtons/micrometer, at least 0.3 Newtons/micrometer, at least 0.4 Newtons/micrometer, at least 0.6 Newtons/micrometer, at least 0.8 Newtons/micrometer, at least 1 Newtons/micrometer, at least 1.25 Newtons/micrometer, at least 1.5 Newtons/micrometer, and/or at least 2 Newtons/micrometer. As another example, the stiffness along the contacting axis may be at most 10 Newtons/micrometer, at most 8 Newtons/micrometer, at most 6 Newtons/micrometer, at most 5 Newtons/micrometer, at most 4 Newtons/micrometer, at most 3 Newtons/micrometer, at most 2 Newtons/micrometer, and/or at most 1 Newtons/micrometer.

As yet another example, the stiffness in all directions that are perpendicular to the contacting axis may be at least 0.1 Newtons/micrometer, at least 1 Newtons/micrometer, at least 5 Newtons/micrometer, at least 10 Newtons/micrometer, at least 15 Newtons/micrometer, at least 20 Newtons/micrometer, at least 25 Newtons/micrometer, at least 30 Newtons/micrometer, at least 35 Newtons/micrometer, at least 40 Newtons/micrometer, at least 50 Newtons/micrometer, at least 75 Newtons/micrometer, at least 100 Newtons/micrometer, at least 150 Newtons/micrometer, at least 200 Newtons/micrometer, at least 250 Newtons/micrometer, at least 300 Newtons/micrometer, at least 350 Newtons/micrometer, and/or at least 400 Newtons/micrometer. Additionally or alternatively, the stiffness in all directions that are perpendicular to the contacting axis may be at most 2000 Newtons/micrometer, at most 1750 Newtons/micrometer, at most 1500 Newtons/micrometer, at most 1250 Newtons/micrometer, at most 1000 Newtons/micrometer, at most 900 Newtons/micrometer, at most 800 Newtons/micrometer, at most 700 Newtons/micrometer, at most 600 Newtons/micrometer, at most 500 Newtons/micrometer, at most 400 Newtons/micrometer, at most 300 Newtons/micrometer, at most 200 Newtons/micrometer, at most 100 Newtons/micrometer, and/or at most 50 Newtons/micrometer.

Stated another way, a ratio of a minimum stiffness of the orientation-regulating structure in all directions that are perpendicular to the contacting axis to the stiffness of the orientation-regulating structure along the contacting axis may be at least 2, at least 4, at least 6, at least 8, at least 10, at least 15, at least 20, at least 25, at least 30, at least 35, at least 40, at least 45, at least 50, at least 60, at least 70, at least 80, at least 90, at least 100, at least 150, at least 200, at least 250, and/or at least 300. Additionally or alternatively, the ratio may be at most 1500, at most 1250, at most 1000, at most 750, at most 500, at most 400, at most 350, at most 300, at most 250, at most 200, at most 150, at most 100, and/or at most 50.

Orientation-regulating structure 130 may be configured to permit contacting structure 110 and/or backing plate 120 to deflect toward support frame 150 a threshold distance from the undeflected orientation upon contact between the contacting structure and the DUT and/or without damage to the orientation-regulating structure. Stated another way, the threshold distance may be a difference between undeflected distance 161 of FIG. 2 and a maximum value of deflected distance 163 of FIG. 3 that may be provided by orientation-regulating structure 130 without damage thereto. Examples of the threshold distance include threshold distances of at least 25 micrometers, at least 50 micrometers, at least 75 micrometers, at least 100 micrometers, least 150 micrometers, at least 200 micrometers, at least 300 micrometers, at least 400 micrometers, at least 500 micrometers, at least 600 micrometers, or at least 700 micrometers. Additionally or alternatively, the threshold distance may be at most 2000 micrometers, at most 1750 micrometers, at most 1500 micrometers, at most 1250 micrometers, at most 1000 micrometers, at most 750 micrometers, at most 500 micrometers, at most 300 micrometers, at most 250 micrometers, at most 200 micrometers, and/or at most 150 micrometers.

As discussed, orientation-regulating structure 130 resists rotation of contacting assembly 110 and/or of backing plate 120 relative to support frame 150. However, orientation-regulating structure 130 may not be entirely rigid with respect to rotation of the contacting assembly and/or of the backing plate. As an example, orientation-regulating structure 130 may be configured such that, when contacting structure 110 and/or backing plate 120 deflects toward support frame 150 the threshold distance from the undeflected orientation, and regardless of a location and/or direction of a force that causes the deflection, contacting assembly 110 and/or backing plate 120 rotates less than a threshold angle relative to support frame 150. Examples of the threshold angle include threshold angles of less than 2 degrees, less than 1.5 degrees, less than 1 degree, less than 0.5 degrees, less than 0.25 degrees, less than 0.1 degree, less than 0.05 degrees, less than 0.01 degrees, less than 0.005 degrees, or less than 0.001 degrees.

This deflection of contacting structure 110 and/or backing plate 120 may be significantly larger than the overdrive that may be permitted solely by deflection of conductive probes 112. As examples, the orientation-regulating structure may permit deflection of contacting structure 110 and/or of backing plate 120 that may be at least 20, at least 40, at least 60, at least 80, at least 100, at least 120, at least 140, at least 160, at least 180, or at least 200 times larger than the deflection of conductive probes 112.

Orientation-regulating structure 130 also may be formed and/or defined in any suitable manner. As an example, the orientation-regulating structure may include and/or be a monolithic orientation-regulating structure that may be formed, machined, molded, and/or printed to form a single-continuous structure. As another example, the orientation-regulating structure may include and/or be a composite orientation-regulating structure that may be formed from a plurality of discrete, distinct, and/or separate components that may be operatively attached to one another to form and/or define the orientation-regulating structure.

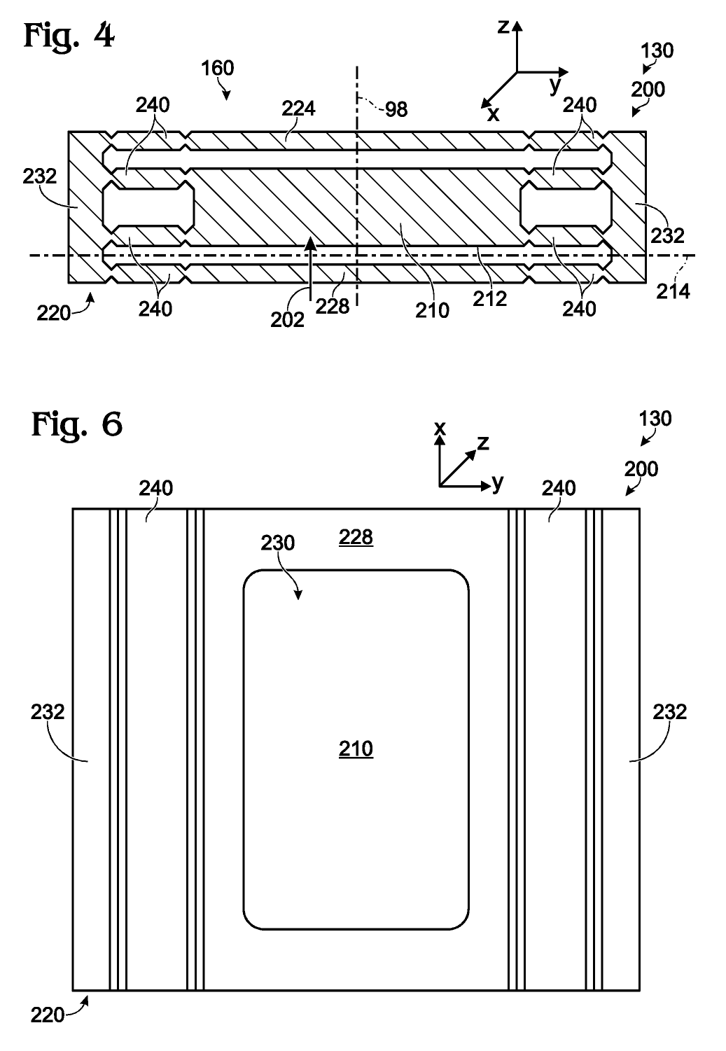

An example of orientation-regulating structure 130 includes a compound linear flexure 200. Examples of compound linear flexures 200, which may be included in and/or utilized with probe head assemblies 100 and/or orientation-regulating structures 130 of FIGS. 1-3, are illustrated in FIGS. 4-7 and discussed in more detail herein with reference thereto.

Contacting structure 110 may include any suitable structure that may include conductive probes 112. As an example, and as illustrated in FIG. 1, contacting structure 110 may include a resilient dielectric body, or membrane, 116 that supports conductive probes 112. As another example, contacting structure 110 may include and/or be a probe card that includes the plurality of conductive probes.

Similarly, conductive probes 112 may include and/or be any suitable structure that may be adapted, configured, designed, and/or constructed to physically and electrically contact the corresponding contact pads on the DUT. As examples, conductive probes 112 may include one or more of a beam probe, a rocking beam probe, a needle probe, and/or a probe that extends from, forms a portion of, and/or is defined by the probe card. As additional examples, conductive probes 112 may include and/or be metallic conductive probes 112, electrically conductive probes 112, and/or flexible conductive probes 112.

It is within the scope of the present disclosure that contacting structure 110 may be retained within probe head assembly 100 in any suitable manner. As an example, and as illustrated in FIG. 1, contacting structure 110 may be adhered to backing plate 120 and/or to orientation-regulating structure 130, such as with and/or utilizing an adhesive 118. As another example, contacting structure 110 may extend past backing plate 120 and/or orientation-regulating structure 130 and/or may be tensioned across the backing plate and/or across the orientation-regulating structure. This is illustrated in dashed lines in FIG. 1. In such a configuration, probe head assembly 100 further may include a contacting structure mount 111, which may operatively attach contacting structure 110 to another portion of probe head assembly 100, such as to support frame 150.

Backing plate 120, when present, may include any suitable structure that may support contacting structure 110 and/or that may extend at least partially between contacting structure 110 and orientation-regulating structure 130. As discussed, backing plate 120 may include and/or be a rigid, or at least substantially rigid, backing plate 120. As such, backing plate 120 may resist deformation when probe head assembly 100 and/or contacting structure 110 thereof contacts DUT 94. Such a configuration may facilitate contact between all probe tips 114 of all conductive probes 112 and/or of all contacting regions 119 with corresponding contact pads 96 of DUT(s) 94.

Stated another way, contacting structure-supporting surface 122 of backing plate 120 may be planar, or at least substantially planar. As such, backing plate 120 may maintain probe tips 114 of conductive probes 112 in a single, or at least substantially within a single, contacting plane 115. Such a configuration once again may facilitate contact between all probe tips 114 of all conductive probes 112 and/or of all contacting regions 119 with corresponding contact pads 96 of DUT(s) 94.

It is within the scope of the present disclosure that backing plate 120 may include and/or be any suitable structure. As an example, backing plate 120 may include and/or be a single, continuous, single-piece, and/or monolithic backing plate 120. As another example, backing plate 120 may include and/or be a multi-component, or composite, backing plate 120, which may be formed from a plurality of components and/or materials that may be operatively attached, adhered, and/or otherwise affixed to one another.

An example of such a multi-component backing plate includes a space transformer 124, as illustrated in FIG. 1. When backing plate 120 includes space transformer 124, the backing plate may include a plurality of electrical conduits 126. Each electrical conduit 126 may be in electrical communication with a corresponding conductive probe 112. In addition, each electrical conduit 126 may extend between contacting structure-supporting surface 122 and contacting structure-opposed surface 123. As such, space transformer 124 may be configured to permit test signals 42 and/or resultant signals 44 to be conveyed therethrough, as illustrated in dotted lines in FIG. 1. However, this is not required, and test signals 42 and/or resultant signals 44 also may be conveyed around and/or past backing plate 120, orientation-regulating structure 130, and/or support frame 150, as also illustrated in dotted lines in FIG. 1.

Support frame 150 may include any suitable structure that may, or that may be configured to, support contacting structure 110, support backing plate 120, and/or support orientation-regulating structure 130. As examples, support frame 150 may include and/or be a rigid support frame, an at least substantially rigid support frame, a metallic support frame, and/or an at least partially metallic support frame.

Chuck 30 may include any suitable structure that may include and/or define support surface 32 and/or that may operatively support substrate 90. As examples, chuck 30 may include a vacuum chuck and/or a temperature-controlled chuck.

Similarly, chuck stage 34 may include any suitable structure that may be configured to operatively translate and/or rotate chuck 30, and thus substrate 90, with respect to, or relative to, probe head assembly 100. As examples, chuck stage 34 may include one or more of a linear actuator, a rotary actuator, a piezoelectric actuator, a stepper motor, a lead screw and nut assembly, a ball screw assembly, a rack and pinion assembly, a micrometer, an automated actuator, and/or a manual actuator.

Signal generation and analysis assembly 40 may include and/or be any suitable structure that may be adapted, configured, designed, and/or constructed to provide one or more test signals 42 to one or more DUTs 94 and/or to receive one or more resultant signals 44 from one or more DUTs 94. As examples, signal generation and analysis assembly 40 may include a network analyzer, a volt meter, a current meter, an electrical power source, an AC power source, and/or a DC power source.

Enclosure 50 may include and/or be any suitable structure that may form, define, and/or at least partially bound enclosed volume 52. As examples, enclosure 50 may include one or more of an environmentally controlled enclosure, a temperature-controlled enclosure, a shielded enclosure, an electromagnetically shielded enclosure, a humidity-controlled enclosure, and/or a sealed enclosure. As illustrated in FIG. 1, enclosure 50 and/or enclosed volume 52 thereof may contain, house, and/or include at least a portion, or even all, of one or more of chuck 30, substrate 90, contacting structure 110, backing plate 120, orientation-regulating structure 130, support frame 150, and/or probe head assembly 100.

Substrate 90 may include and/or be any suitable structure that may support, include, and/or have formed thereon DUT 94. Examples of substrate 90 include a wafer, a semiconductor wafer, a silicon wafer, and/or a gallium arsenide wafer.

Similarly, DUT 94 may include and/or be any suitable structure that may be probed and/or tested by probe system 20. As examples, DUT 94 may include a semiconductor device, an electronic device, a logic device, a power device, a switching device, and/or a transistor.

FIGS. 4-8 provide less schematic examples of orientation-regulating structures 130 that may be included in and/or utilized with probe head assemblies 100, according to the present disclosure. Orientation-regulating structures 130 of FIGS. 4-8 may include and/or be more detailed and/or alternative representations of orientation-regulating structures 130 of FIGS. 1-3, and any of the structures, functions, and/or features that are disclosed herein with reference to orientation-regulating structures 130 of FIGS. 4-8 may be included in and/or utilized with probe head assemblies 100 and/or orientation-regulating structures 130 of FIGS. 1-3 without departing from the scope of the present disclosure. Similarly, any of the structures, functions, and/or features that are disclosed herein with reference to probe head assemblies 100 and/or orientation-regulating structures 130 of FIGS. 1-3 may be included in and/or utilized with orientation-regulating structures 130 of FIGS. 4-8 without departing from the scope of the present disclosure.

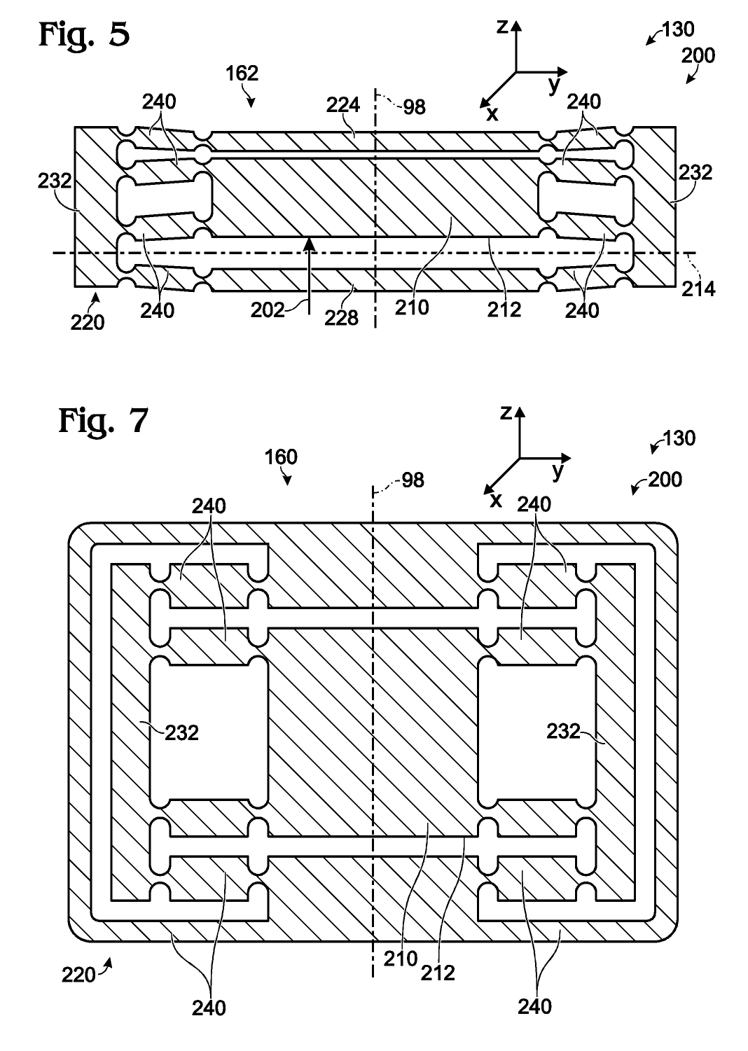

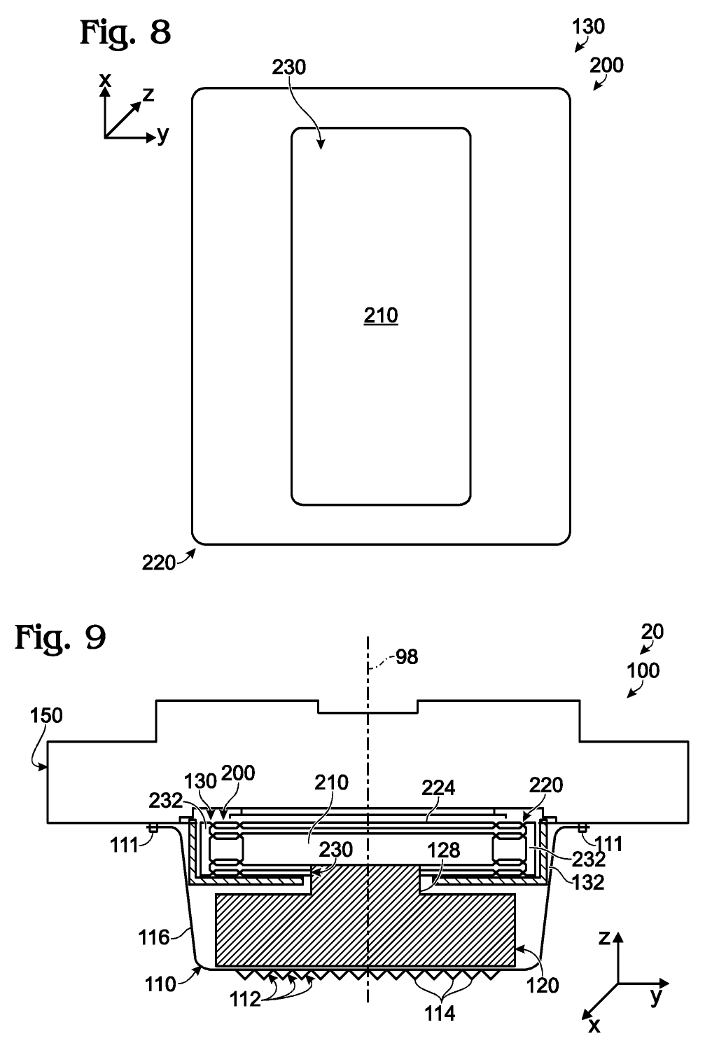

FIG. 4 is a schematic side view of an example of an orientation-regulating structure 130 according to the present disclosure, in the form of a compound linear flexure 200, illustrated in an undeflected relative orientation 160, while FIG. 5 is a schematic side view of the compound linear flexure of FIG. 4 illustrated in a deflected relative orientation 162. FIG. 6 is a schematic bottom view of the orientation-regulating structure of FIGS. 4-5. FIG. 7 is a schematic side view of another example of an orientation-regulating structure 130 according to the present disclosure, in the form of a compound linear flexure 200, in undeflected relative orientation 160. FIG. 8 is a schematic bottom view of the orientation-regulating structure of FIG. 7.

Compound linear flexures 200 of FIGS. 4-8 include a platform 210 that is configured to deflect, upon application of a force 202, from undeflected relative orientation 160 of FIGS. 4 and 7, to deflected relative orientation 162 of FIG. 5. As discussed in more detail herein, this deflection of platform 210 may be along, or at least substantially along, a contacting axis 98 regardless of a direction of force 202. Stated another way, compound linear flexures 200 may be configured such that a DUT-facing side 212 of platform 210 may translate along contacting axis 98 but may not pivot and/or rotate about the contacting axis, or may pivot and/or rotate by less than a threshold amount, as the compound linear flexure transitions between undeflected relative orientation 160 and deflected relative orientation 162. Stated yet another way, compound linear flexures 200 may be configured such that, as the compound linear flexure transitions from the undeflected state to the deflected state and/or from the deflected state to the undeflected state, DUT-facing side 212 of platform 210 remains parallel, or at least substantially parallel, to a single reference plane 214, as illustrated in FIGS. 4-5.

As further illustrated in FIGS. 4-8, compound linear flexures 200 may include a flexure frame 220 that at least partially surrounds platform 210 and that is in mechanical communication with platform 210 via a plurality of flexure elements 240. As illustrated in FIGS. 4-5, flexure elements 240 may be configured to flex and thereby to permit the translational motion of platform 210 along contacting axis 98. Thus, flexure elements 240 also may be referred to herein as flexibly connecting flexure frame 220 and platform 210. However, and as discussed, flexure elements 240 may be adapted, configured, shaped, sized, designed, and/or oriented only to permit the translational motion of platform 210 along contacting axis 98 while restricting and/or limiting translational motion of platform 210 along axes that are perpendicular to the contacting axis, such as the X and Y-axes of FIGS. 4-8. In addition, flexure elements 240 may be adapted, configured, shaped, sized, designed, and/or orientated to resist rotation of platform 210 about any axis, or all axes, such as the X, Y, and/or Z-axes of FIGS. 4-8.

As illustrated in FIGS. 4-6, flexure frame 220 may include a plurality of components, including a frame-facing plate 224, a frame-opposed plate 228, and a pair of side plates 232 that may be interconnected via flexure elements 240. Alternatively, and as illustrated in FIGS. 7-8, flexure frame 220 may surround platform 210 and side plates 232, with the flexure frame being operatively connected to side plates 232 via respective flexure elements 240 and side plates 232 further being operatively connected to platform 210 via different flexure elements 240.

As illustrated in FIGS. 6 and 8, and regardless of an exact configuration of flexure frame 220, the flexure frame may include and/or define an aperture 230. Aperture 230 may permit mechanical communication between platform 210 and contacting structure 110 and/or backing plate 120, as discussed in more detail herein with reference to FIG. 9. Stated another way, platform 210 may be accessible to contacting structure 110 and/or backing plate 120 via aperture 230. Stated yet another way, contacting structure 110 and/or backing plate 120 may be operatively attached to platform 210, such as via aperture 230.

FIG. 9 is a less schematic side view of an example of a probe head assembly 100 that includes a compound linear flexure 200, according to the present disclosure. Probe head assembly 100 of FIG. 9 may include and/or be a more detailed and/or alternative representation of probe had assemblies 100 of FIGS. 1-3, and any of the structures, functions, and/or features that are disclosed herein with reference to probe head assembly 100 of FIG. 9 may be included in and/or utilized with probe head assemblies 100 of FIGS. 1-3 without departing from the scope of the present disclosure. Similarly, any of the structures, functions, and/or features that are disclosed herein with reference to probe head assemblies 100 of FIGS. 1-3 may be included in and/or utilized with probe head assembly 100 of FIG. 9 without departing from the scope of the present disclosure.

Similar to probe head assemblies 100 of FIGS. 1-3, probe head assembly 100 of FIG. 9 includes a contacting structure 110, a backing plate 120, an orientation-regulating structure 130, and a support frame 150. Contacting structure 110 includes a plurality of conductive probes 112 with corresponding probe tips 114 that are supported by a resilient dielectric body 116. The resilient dielectric body also may be referred to herein as a membrane 116 and may be tensioned across backing plate 120 and operatively attached to support frame 150 via contacting structure mount 111.

Orientation-regulating structure 130 includes compound linear flexure 200, which may be at least substantially similar to compound linear flexure 200 of any of FIGS. 4-8. Compound linear flexure 200 includes a platform 210 and an aperture 230. Backing plate 120 includes an extension region 128 that extends through aperture 230 and operatively contacts platform 210. Thus, contacting structure 110 is in mechanical communication with platform 210 via backing plate 120. In addition, compound linear flexure 200 permits contacting structure 110 to translate along contacting axis 98 but restricts any other motion of the contacting structure, as discussed herein.

Compound linear flexure 200 further includes a flexure frame 220, which may include a support frame-facing plate 224, and the compound linear flexure may be operatively attached to support frame 150 via flexure frame 220 and/or via support frame-facing plate 224 thereof. As an example, and as illustrated in FIG. 9, an orientation-regulating structure mount 132 may operatively attach compound linear flexure 200, flexure frame 220 thereof, and/or support frame-facing plate 224 thereof to support frame 150.

As used herein, the term “and/or” placed between a first entity and a second entity means one of (1) the first entity, (2) the second entity, and (3) the first entity and the second entity. Multiple entities listed with “and/or” should be construed in the same manner, i.e., “one or more” of the entities so conjoined. Other entities may optionally be present other than the entities specifically identified by the “and/or” clause, whether related or unrelated to those entities specifically identified. Thus, as a non-limiting example, a reference to “A and/or B,” when used in conjunction with open-ended language such as “comprising” may refer, in one embodiment, to A only (optionally including entities other than B); in another embodiment, to B only (optionally including entities other than A); in yet another embodiment, to both A and B (optionally including other entities). These entities may refer to elements, actions, structures, steps, operations, values, and the like.

As used herein, the phrase “at least one,” in reference to a list of one or more entities should be understood to mean at least one entity selected from any one or more of the entity in the list of entities, but not necessarily including at least one of each and every entity specifically listed within the list of entities and not excluding any combinations of entities in the list of entities. This definition also allows that entities may optionally be present other than the entities specifically identified within the list of entities to which the phrase “at least one” refers, whether related or unrelated to those entities specifically identified. Thus, as a non-limiting example, “at least one of A and B” (or, equivalently, “at least one of A or B,” or, equivalently “at least one of A and/or B”) may refer, in one embodiment, to at least one, optionally including more than one, A, with no B present (and optionally including entities other than B); in another embodiment, to at least one, optionally including more than one, B, with no A present (and optionally including entities other than A); in yet another embodiment, to at least one, optionally including more than one, A, and at least one, optionally including more than one, B (and optionally including other entities). In other words, the phrases “at least one,” “one or more,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C” and “A, B, and/or C” may mean A alone, B alone, C alone, A and B together, A and C together, B and C together, A, B and C together, and optionally any of the above in combination with at least one other entity.

In the event that any patents, patent applications, or other references are incorporated by reference herein and (1) define a term in a manner that is inconsistent with and/or (2) are otherwise inconsistent with, either the non-incorporated portion of the present disclosure or any of the other incorporated references, the non-incorporated portion of the present disclosure shall control, and the term or incorporated disclosure therein shall only control with respect to the reference in which the term is defined and/or the incorporated disclosure was present originally.

As used herein the terms “adapted” and “configured” mean that the element, component, or other subject matter is designed and/or intended to perform a given function. Thus, the use of the terms “adapted” and “configured” should not be construed to mean that a given element, component, or other subject matter is simply “capable of” performing a given function but that the element, component, and/or other subject matter is specifically selected, created, implemented, utilized, programmed, and/or designed for the purpose of performing the function. It is also within the scope of the present disclosure that elements, components, and/or other recited subject matter that is recited as being adapted to perform a particular function may additionally or alternatively be described as being configured to perform that function, and vice versa.

As used herein, the phrase, “for example,” the phrase, “as an example,” and/or simply the term “example,” when used with reference to one or more components, features, details, structures, embodiments, and/or methods according to the present disclosure, are intended to convey that the described component, feature, detail, structure, embodiment, and/or method is an illustrative, non-exclusive example of components, features, details, structures, embodiments, and/or methods according to the present disclosure. Thus, the described component, feature, detail, structure, embodiment, and/or method is not intended to be limiting, required, or exclusive/exhaustive; and other components, features, details, structures, embodiments, and/or methods, including structurally and/or functionally similar and/or equivalent components, features, details, structures, embodiments, and/or methods, are also within the scope of the present disclosure.

Examples of probe head assemblies and probe systems according to the present disclosure are presented in the following enumerated paragraphs. It is within the scope of the present disclosure that an individual step of a method recited herein, including in the following enumerated paragraphs, may additionally or alternatively be referred to as a “step for” performing the recited action.

A1. A probe head assembly configured to contact a device under test (DUT) along a contacting axis, the probe head assembly comprising:

a contacting structure including a plurality of conductive probes configured to physically and electrically contact corresponding contact pads on the DUT;

a compound linear flexure; and

a support frame configured to support the contacting structure and the compound linear flexure, wherein:
(i) the compound linear flexure supports the contacting structure and extends at least partially between the contacting structure and the support frame; and
(ii) the compound linear flexure is configured to permit translational motion of the contacting structure relative to the support frame along the contacting axis and to resist translational motion of the contacting structure relative to the support frame in any direction that is, or all directions that are, perpendicular, or at least substantially perpendicular, to the contacting axis.

A2. The probe head assembly of paragraph A1, wherein the probe head assembly further includes a backing plate that supports the contacting structure and extends at least partially between the contacting structure and the compound linear flexure.

A3. The probe head assembly of paragraph A2, wherein the backing plate is a rigid, or at least substantially rigid, backing plate.

B1. A probe head assembly configured contact a device under test (DUT) along a contacting axis, the probe head assembly comprising:

a contacting structure including a plurality of conductive probes configured to physically and electrically contact corresponding contact pads on the DUT;

optionally a rigid, or at least substantially rigid, backing plate;

an orientation-regulating structure; and

a support frame configured to support the contacting structure, the orientation-regulating structure, and optionally the backing plate, wherein:
(i) the backing plate optionally supports the contacting structure and extends at least partially between the contacting structure and the orientation-regulating structure;
(ii) the orientation-regulating structure supports the contacting structure, optionally via the backing plate, and extends at least partially between the contacting structure and the support frame, and optionally at least partially between the backing plate and the support frame;
(iii) the orientation-regulating structure is configured to permit translational motion of the contacting structure, and optionally the backing plate, relative to the support frame along the contacting axis;
(iv) the orientation-regulating structure is configured to resist translational motion of the contacting structure, and optionally the backing plate, relative to the support frame in any direction that is, or in all directions that are perpendicular, or at least substantially perpendicular, to the contacting axis; and
(v) the orientation-regulating structure is configured to resist rotational motion of the contacting structure, and optionally the backing plate, relative to the support frame about any axis, or all axes.

C1. The probe head assembly of any of paragraphs A2-B1, wherein the backing plate is a monolithic backing plate.

C2. The probe head assembly of any of paragraphs A2-C1, wherein the backing plate is configured to resist deformation when the probe head assembly contacts the DUT.

C3. The probe head assembly of any of paragraphs A2-C2, wherein each of the plurality of conductive probes includes a corresponding probe tip, and further wherein the backing plate is configured to maintain the probe tip of each conductive probe in the plurality of conductive probes in a single, or at least substantially within a single, contacting plane.

C4. The probe head assembly of any of paragraphs A2-C3, wherein the backing plate is a space transformer.

C5. The probe head assembly of paragraph C4, wherein the space transformer includes a plurality of electrical conduits, and further wherein each of the plurality of electrical conduits is in electrical communication with a corresponding one of the plurality of conductive probes.

C6. The probe head assembly of paragraph C5, wherein the space transformer includes a/the contacting structure-supporting surface and a contacting structure-opposed surface, and further wherein each of the plurality of electrical conduits extends between the contacting structure-supporting surface and the contacting structure-opposed surface.

C7. The probe head assembly of any of paragraphs A1-C6, wherein the orientation-regulating structure is configured to resist tilting of the contacting structure relative to the support frame when the probe head assembly operatively contacts the DUT.

C8. The probe head assembly of any of paragraphs A1-C7, wherein a/the backing plate includes a contacting structure-supporting surface, wherein the support frame includes an orientation-regulating structure-supporting surface, and further wherein the orientation-regulating structure is configured to maintain the contacting structure-supporting surface parallel, or at least substantially parallel, to the orientation-regulating structure-supporting surface during translational motion of the backing plate relative to the support frame along the contacting axis.

C9. The probe head assembly of any of paragraphs A1-C8, wherein a/the backing plate includes a/the contacting structure-supporting surface, wherein the support frame includes an/the orientation-regulating structure-supporting surface, and further wherein the orientation-regulating structure is configured to maintain a fixed, or at least substantially fixed, angle of intersection between a plane that is defined by the contacting structure-supporting surface and a plane that is defined by the orientation-regulating structure-supporting surface during translational motion of the backing plate relative to the support frame along the contacting axis.

C10. The probe head assembly of any of paragraphs A1-C9, wherein the orientation-regulating structure is configured to resist rotation of the contacting structure relative to the support frame when a torque is applied to the contacting structure via contact between the contacting structure and the DUT.

C11. The probe head assembly of any of paragraphs A1-C10, wherein, prior to contact between the DUT and the contacting structure, the probe head assembly defines an undeflected relative orientation between the contacting structure and the support frame, and further wherein, upon deflection from the undeflected relative orientation to a deflected relative orientation, which is responsive to contact between the contacting structure and the DUT, the orientation-regulating structure exhibits a restoring force on the contacting structure that urges the probe head assembly toward the undeflected relative orientation.

C12. The probe head assembly of paragraph C11, wherein a magnitude of the restoring force is proportional, and optionally linearly proportional, to a distance that the contacting structure is deflected from the undeflected relative orientation.

C13. The probe head assembly of any of paragraphs A1-C12, wherein the orientation-regulating structure permits translational relative motion between the contacting structure and the support frame along a permitted degree of freedom and resists relative motion between the contacting structure and the support frame in all other degrees of freedom.

C14. The probe head assembly of any of paragraphs A1-C13, wherein the orientation-regulating structure exhibits a stiffness along the contacting axis of at least one of:
(i) at least 0.01 Newtons/micrometer, at least 0.05 Newtons/micrometer, at least 0.1 Newtons/micrometer, at least 0.2 Newtons/micrometer, at least 0.3 Newtons/micrometer, at least 0.4 Newtons/micrometer, at least 0.6 Newtons/micrometer, at least 0.8 Newtons/micrometer, at least 1 Newtons/micrometer, at least 1.25 Newtons/micrometer, at least 1.5 Newtons/micrometer, or at least 2 Newtons/micrometer; and
(ii) at most 10 Newtons/micrometer, at most 8 Newtons/micrometer, at most 6 Newtons/micrometer, at most 5 Newtons/micrometer, at most 4 Newtons/micrometer, at most 3 Newtons/micrometer, at most 2 Newtons/micrometer, or at most 1 Newtons/micrometer.

C15. The probe head assembly of any of paragraphs A1-C14, wherein the orientation-regulating structure exhibits a stiffness in all directions that are perpendicular to the contacting axis of at least one of:
(i) at least 0.1 Newtons/micrometer, at least 1 Newtons/micrometer, at least 5 Newtons/micrometer, at least 10 Newtons/micrometer, at least 15 Newtons/micrometer, at least 20 Newtons/micrometer, at least 25 Newtons/micrometer, at least 30 Newtons/micrometer, at least 35 Newtons/micrometer, at least 40 Newtons/micrometer, at least 50 Newtons/micrometer, at least 75 Newtons/micrometer, at least 100 Newtons/micrometer, at least 150 Newtons/micrometer, at least 200 Newtons/micrometer, at least 250 Newtons/micrometer, at least 300 Newtons/micrometer, at least 350 Newtons/micrometer, or at least 400 Newtons/micrometer, and
(ii) at most 2000 Newtons/micrometer, at most 1750 Newtons/micrometer, at most 1500 Newtons/micrometer, at most 1250 Newtons/micrometer, at most 1000 Newtons/micrometer, at most 900 Newtons/micrometer, at most 800 Newtons/micrometer, at most 700 Newtons/micrometer, at most 600 Newtons/micrometer, at most 500 Newtons/micrometer, at most 400 Newtons/micrometer, at most 300 Newtons/micrometer, at most 200 Newtons/micrometer, at most 100 Newtons/micrometer, or at most 50 Newtons/micrometer.

C16. The probe head assembly of any of paragraphs A1-C15, wherein a ratio of a minimum stiffness of the orientation-regulating structure in all directions that are perpendicular to the contacting axis to a stiffness of the orientation-regulating structure along the contacting axis is at least one of:
(i) at least 2, at least 4, at least 6, at least 8, at least 10, at least 15, at least 20, at least 25, at least 30, at least 35, at least 40, at least 45, at least 50, at least 60, at least 70, at least 80, at least 90, at least 100, at least 150, at least 200, at least 250, or at least 300; and
(ii) at most 1500, at most 1250, at most 1000, at most 750, at most 500, at most 400, at most 350, at most 300, at most 250, at most 200, at most 150, at most 100, or at most 50.

C17. The probe head assembly of any of paragraphs A1-C16, wherein, upon contact between the contacting structure and the DUT, the orientation-regulating structure is configured to permit the contacting structure to deflect toward the support frame a threshold distance along the contacting axis, optionally without damage to the orientation-regulating structure.

C18. The probe head assembly paragraph C17, wherein the threshold distance is at least one of:
(i) at least 25 micrometers, at least 50 micrometers, at least 75 micrometers, at least 100 micrometers, at least 150 micrometers, at least 200 micrometers, at least 300 micrometers, at least 400 micrometers, at least 500 micrometers, at least 600 micrometers, or at least 700 micrometers; and
(ii) at most 2000 micrometers, at most 1750 micrometers, at most 1500 micrometers, at most 1250 micrometers, at most 1000 micrometers, at most 750 micrometers, at most 500 micrometers, at most 300 micrometers, at most 250 micrometers, at most 200 micrometers, or at most 150 micrometers.

C19. The probe head assembly of any of paragraphs A1-C18, wherein the orientation-regulating structure is a monolithic orientation-regulating structure.

C20. The probe head assembly of any of paragraphs A1-C19, wherein the orientation-regulating structure is a composite orientation-regulating structure formed from a plurality of components that are operatively attached to one another to define the orientation-regulating structure.

C21. The probe head assembly of any of paragraphs A1-C20, wherein the orientation-regulating structure includes, and optionally is, a/the compound linear flexure.

C22. The probe head assembly of paragraph C21, wherein the compound linear flexure includes a platform, which is operatively attached to the contacting structure, optionally via the backing plate, a support frame-facing plate, which is operatively attached to the support frame, and a plurality of flexure elements that operatively attach the platform to the support frame-facing plate.

C23. The probe head assembly of any of paragraphs A1-C22, wherein the orientation-regulating structure does not include a coil spring, or an array of coil springs.

C24. The probe head assembly of any of paragraphs A1-C23, wherein the orientation-regulating structure does not include a gimbal mount.

C25. The probe head assembly of any of paragraphs A1-C24, wherein the contacting structure further includes a resilient dielectric body, and further wherein the plurality of conductive probes is supported by the resilient dielectric body.

C26. The probe head assembly of any of paragraphs A1-C25, wherein the contacting structure is adhered to a/the backing plate with an adhesive.

C27. The probe head assembly of any of paragraphs A1-C26, wherein the contacting structure is tensioned across a/the backing plate.

C28. The probe head assembly of any of paragraphs A1-C27, wherein the DUT is supported by a substrate that includes a plurality of DUTs, and further wherein the contacting structure includes a plurality of contacting regions, wherein each of the plurality of contacting regions is configured to contact a corresponding one of the plurality of DUTs.

C29. The probe head assembly of any of paragraphs A1-C28, wherein the support frame is a rigid, or at least substantially rigid, support frame.

D1. A probe system, comprising:

the probe head assembly of any of paragraphs A1-C29;

a chuck including a support surface configured to operatively support a/the substrate that includes the DUT; and

a signal generation and analysis assembly configured to at least one of:
(i) provide a test signal to the DUT via the probe head assembly; and
(ii) receive a resultant signal from the DUT via the probe head assembly.

D2. The probe system of paragraph D1, wherein the probe system further includes an enclosure defining an enclosed volume that includes the chuck, the support surface, and at least a portion of the probe head assembly.

D3. The probe system of any of paragraphs D1-D2, wherein the substrate includes a/the plurality of DUTs that is oriented in an array on a surface of the substrate, wherein the contacting structure includes a/the plurality of spaced-apart contacting regions oriented to contact a corresponding subset of the plurality of DUTs.

D4. The probe system of paragraph D3, wherein the probe system includes the substrate, wherein the probe head assembly is contacting the substrate, wherein the probe head assembly is oriented such that fewer than all of the plurality of spaced-apart contacting regions is contacting a corresponding DUT and a torque is applied to the probe head assembly by the substrate, and further wherein the orientation-regulating structure resists rotation of the contacting structure relative to the support frame due to the torque.

### INDUSTRIAL APPLICABILITY

The probe heads and probe systems disclosed herein are applicable to the semiconductor manufacturing and test industries.

It is believed that the disclosure set forth above encompasses multiple distinct inventions with independent utility. While each of these inventions has been disclosed in its preferred form, the specific embodiments thereof as disclosed and illustrated herein are not to be considered in a limiting sense as numerous variations are possible. The subject matter of the inventions includes all novel and non-obvious combinations and subcombinations of the various elements, features, functions and/or properties disclosed herein. Similarly, where the claims recite “a” or “a first” element or the equivalent thereof, such claims should be understood to include incorporation of one or more such elements, neither requiring nor excluding two or more such elements.

It is believed that the following claims particularly point out certain combinations and subcombinations that are directed to one of the disclosed inventions and are novel and non-obvious. Inventions embodied in other combinations and subcombinations of features, functions, elements and/or properties may be claimed through amendment of the present claims or presentation of new claims in this or a related application. Such amended or new claims, whether they are directed to a different invention or directed to the same invention, whether different, broader, narrower, or equal in scope to the original claims, are also regarded as included within the subject matter of the inventions of the present disclosure.

1. A probe head assembly configured to contact a device under test (DUT) along a contacting axis, the probe head assembly comprising:
a contacting structure including a plurality of conductive probes configured to physically and electrically contact corresponding contact pads on the DUT;
a compound linear flexure; and
a support frame configured to support the contacting structure and the compound linear flexure, wherein:
(i) the compound linear flexure supports the contacting structure and extends at least partially between the contacting structure and the support frame; and
(ii) the compound linear flexure is configured to permit translational motion of the contacting structure relative to the support frame along the contacting axis and to resist translational motion of the contacting structure relative to the support frame in any direction that is at least substantially perpendicular to the contacting axis.

2. The probe head assembly of claim 1, wherein the probe head assembly further includes a backing plate that supports the contacting structure and extends at least partially between the contacting structure and the compound linear flexure.

3. The probe head assembly of claim 2, wherein the backing plate is an at least substantially rigid backing plate.

4. A probe head assembly configured contact a device under test (DUT) along a contacting axis, the probe head assembly comprising:
a contacting structure including a plurality of conductive probes configured to physically and electrically contact corresponding contact pads on the DUT;
an orientation-regulating structure; and
a support frame configured to support the contacting structure and the orientation-regulating structure, wherein:
(i) the orientation-regulating structure supports the contacting structure and extends at least partially between the contacting structure and the support frame;
(ii) the orientation-regulating structure is configured to permit translational motion of the contacting structure relative to the support frame along the contacting axis;
(iii) the orientation-regulating structure is configured to resist translational motion of the contacting structure relative to the support frame in any direction that is at least substantially perpendicular to the contacting axis; and
(iv) the orientation-regulating structure is configured to resist rotational motion of the contacting structure relative to the support frame about any axis.

5. The probe head assembly of claim 4, wherein the probe head assembly further includes an at least substantially rigid backing plate, and further wherein:
(i) the support frame further is configured to support the backing plate; and
(ii) the backing plate supports the contacting structure and extends at least partially between the contacting structure and the orientation-regulating structure such that the orientation-regulating structure supports the contacting structure via the backing plate.

6. The probe head assembly of claim 5, wherein the backing plate is configured to resist deformation when the probe head assembly contacts the DUT.

7. The probe head assembly of claim 5, wherein each of the plurality of conductive probes includes a corresponding probe tip, and further wherein the backing plate is configured to maintain the probe tip of each conductive probe in the plurality of conductive probes in an at least substantially single contacting plane.

8. The probe head assembly of claim 5, wherein the backing plate is a space transformer, wherein the space transformer includes a plurality of electrical conduits, wherein each of the plurality of electrical conduits is in electrical communication with a corresponding one of the plurality of conductive probes, wherein the space transformer includes a contacting structure-supporting surface and a contacting structure-opposed surface, and further wherein each of the plurality of electrical conduits extends between the contacting structure-supporting surface and the contacting structure-opposed surface.

9. The probe head assembly of claim 4, wherein the orientation-regulating structure is configured to resist tilting of the contacting structure relative to the support frame when the probe head assembly operatively contacts the DUT.

10. The probe head assembly of claim 4, wherein the orientation-regulating structure is configured to resist rotation of the contacting structure relative to the support frame when a torque is applied to the contacting structure via contact between the contacting structure and the DUT.

11. The probe head assembly of claim 4, wherein, prior to contact between the DUT and the contacting structure, the probe head assembly defines an undeflected relative orientation between the contacting structure and the support frame, and further wherein, upon deflection from the undeflected relative orientation to a deflected relative orientation, which is responsive to contact between the contacting structure and the DUT, the orientation-regulating structure exhibits a restoring force on the contacting structure that urges the probe head assembly toward the undeflected relative orientation.

12. The probe head assembly of claim 4, wherein the orientation-regulating structure permits translational relative motion between the contacting structure and the support frame along a permitted degree of freedom and resists relative motion between the contacting structure and the support frame in all other degrees of freedom.

13. The probe head assembly of claim 4, wherein the orientation-regulating structure exhibits a stiffness along the contacting axis of at most 10 Newtons/micrometer.

14. The probe head assembly of claim 13, wherein the orientation-regulating structure exhibits a stiffness in all directions that are perpendicular to the contacting axis of at least 20 Newtons/meter.

15. The probe head assembly of claim 4, wherein a ratio of a minimum stiffness of the orientation-regulating structure in all directions that are perpendicular to the contacting axis to a stiffness of the orientation-regulating structure along the contacting axis is at least 10.

16. The probe head assembly of claim 4, wherein, upon contact between the contacting structure and the DUT, the orientation-regulating structure is configured to permit the contacting structure to deflect toward the support frame a threshold distance of at least 25 micrometers along the contacting axis.

17. The probe head assembly of claim 4, wherein the orientation-regulating structure includes a compound linear flexure.

18. The probe head assembly of claim 17, wherein the compound linear flexure includes a platform, which is operatively attached to the contacting structure, a support frame-facing plate, which is operatively attached to the support frame, and a plurality of flexure elements that operatively attaches the platform to the support frame-facing plate.

19. A probe system, comprising:
the probe head assembly of claim 4;
a chuck including a support surface configured to operatively support a substrate that includes the DUT; and
a signal generation and analysis assembly configured to at least one of:
(i) provide a test signal to the DUT via the probe head assembly; and
(ii) receive a resultant signal from the DUT via the probe head assembly.

20. The probe system of claim 19, wherein the substrate includes a plurality of DUTs that is oriented in an array on a surface of the substrate, wherein the contacting structure includes a plurality of spaced-apart contacting regions oriented to contact a corresponding subset of the plurality of DUTs, wherein the probe system includes the substrate, wherein the probe head assembly is contacting the substrate, wherein the probe head assembly is oriented such that fewer than all of the plurality of spaced-apart contacting regions is contacting a corresponding DUT of the plurality of DUTs and also such that a torque is applied to the probe head assembly by the substrate, and further wherein the orientation-regulating structure resists rotation of the contacting structure relative to the support frame due to the torque.
